(19) United States
(12) Patent Application Publication
(10) Pub. No.: US 2004/0140474 A1
(43) Pub. Date: Jul. 22, 2004

(54) Semiconductor light-emitting device, method for fabricating the same and method for bonding the same

(75) Inventors: Tetsuzo Ueda, Osaka (JP); Masaaki Yuri, Osaka (JP)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/600,659

(22) Filed: Jun. 23, 2003

(30) Foreign Application Priority Data
Jun. 25, 2002 (JP) 2002-183919

(51) Int. Cl. H01L 27/15

(52) U.S. Cl. 257/79

(57) ABSTRACT

A light-emitting device includes an element structure including at least two semiconductor layers having mutually different conductivity types. A transparent p-side electrode of ITO is formed on the element structure. A bonding pad is formed on a region of the p-side electrode. An n-side electrode made of Ti/Au is formed on the surface of the element structure opposite to the p-side electrode. A metal film made of gold plating with a thickness of about 50 μm is formed, using an Au layer in the n-side electrode as an underlying layer.

### BACKGROUND OF THE INVENTION

The present invention relates to semiconductor light-emitting devices such as diodes emitting short-wavelength light, methods for fabricating the same, and methods for bonding the same.

Group III-V nitride semiconductors generally expressed by the general formula B_{z}AlₓGa_{1-x-y-z}In_{y}N_{1-v-w}AsᵥP_{w} (where 0≦x≦1, 0≦y≦1, 0≦z≦1, 0≦x+y+z≦1, 0≦v≦1, 0≦w≦1 and 0≦v+w≦1), which are generally expressed by BAlGaInNAsP and will be hereinafter referred to as GaN-based semiconductors, have a relatively large forbidden-band width of 3.4 eV at room temperature in the case of gallium nitride (GaN), for example. Thus, such GaN-based semiconductors are expected to be widely applied to, for example, light-emitting devices such as visible-light-emitting diodes producing blue or green light or semiconductor lasers emitting short-wavelength light and transistors such as transistors operable under high temperatures or high-power transistors operable at high speeds. As the light-emitting devices, light-emitting diodes and semiconductor lasers have introduced into the market. In particular, the light-emitting diodes have been put in practical use in various kinds of displaying systems producing blue or green light, large displays and traffic lights. White-light-emitting diodes, which emit light due to excitation of fluorescent materials, have been vigorously researched and developed in increasing the luminance and in improving the luminous efficacy, for the purpose of replacing the prevailing fluorescent lamps and incandescent lamps, i.e., achieving so-called semiconductor lightings.

In the past, it was difficult to grow the GaN-based semiconductors by crystal growth processes, as other wide-gap semiconductors. However, the recent considerable progress of crystal growth techniques mainly using a metal organic chemical vapor deposition (MOCVD) process has put the above light-emitting diodes in practical use.

With regard to crystal growth, it is not easy to form a substrate of gallium nitride (GaN) as a substrate for the growth of a crystal growth layer (an epitaxial layer). Accordingly, the fabrication process cannot be developed on the substrate itself, unlike the case of silicon (Si) or gallium arsenide (GaAs), and in addition, an epitaxial layer cannot be grown on a substrate made of the same material as the epitaxial layer. Therefore, a heteroepitaxial growth using a substrate made of a different material from an epitaxial layer is employed in general.

It is GaN-based semiconductors grown with sapphire used for a substrate that has been most widely used and exhibits the most excellent device characteristics. Since sapphire has the same hexagonal structure as the GaN-based semiconductors and, moreover, is extremely stable to heat, it is suitable for the crystal growth of the GaN-based semiconductors requiring high temperatures of 1000° C. or more. Accordingly, improvements have conventionally been made on the luminance and luminous efficacy of light-emitting diodes, focusing mainly on a GaN-based semiconductor layer grown on a substrate made of sapphire. For example, to obtain high luminance, two aspects are important: increase in internal quantum efficiency achieved by having the crystallinity of the GaN-based semiconductor excellent and suppressing nonluminous recombination; and improvement of light extracting efficiency.

As a result of recent considerable progress of crystal growth technology described above, however, the improvement in internal quantum efficiency is approaching its limit. Therefore, the improvement of light extracting efficiency has become a more important task recently.

Hereinafter, two known techniques for improving the light extracting efficiency will be described with reference to the drawings.

(Prior Art 1)

As shown in FIG. 18, to fabricate a light-emitting diode according to a first prior art, an n-type semiconductor layer 102 of n-type AlGaN, an active layer 103 of InGaN and a p-type semiconductor layer 104 of p-type AlGaN are grown in this order by, for example, an MOCVD process over a substrate 101 of sapphire. Subsequently, part of the n-type semiconductor layer 102 is selectively exposed by dry etching, and an n-side electrode 106 of Ti/Al is formed on the exposed part of the n-type semiconductor layer 102. A transparent p-side electrode 107 of Ni/Au with a thickness of about 10 nm or less is formed on the p-type semiconductor layer 104. A bonding pad 108 of Al is formed on a region of a transparent p-side electrode 107. (see Japanese Laid-Open Publication No. 07-94782)

In this manner, the light-emitting diode of the first prior art can emit light with high luminance because the transparent p-side electrode 107 allows most part of the blue light emitted from the active layer 103 and having a wavelength of, for example, 470 nm to pass through the transparent p-side electrode 107 and to be taken out to the outside. Even in such a case, the emitted light is not taken out sufficiently toward the substrate 101. Therefore, improvement in luminous efficacy has a limitation.

(Prior Art 2)

As shown in FIG. 19, a light-emitting diode according to a second prior art is bonded with a p-type semiconductor layer 104 facing the upper surface of a submount 113 provided with a protection diode, i.e., is so-called flip-chip bonded, and takes out emitted light through a substrate 101 of sapphire. (see Japanese Laid-Open Publication No. 11-191641) In this case, a p-side electrode 110 of Ni is formed on the surface of the p-type semiconductor layer 104 facing the submount 113. Bumps 111 of Ag are formed between the p-side electrode 110 and the submount 113 and between an n-side electrode 106 and the submount 113, respectively. Since the sapphire substrate 101 is made of an insulating material, the electrostatic breakdown voltage is low. Accordingly, the submount 113 with the protection diode is used in order to prevent a surge current from flowing in a chip upon the application of a surge voltage.

In addition, Ag constituting the bumps 111 has a high reflectance with respect to blue light, and therefore the electrode structure having such a high reflectance and the flip-chip bonding allow most part of blue light emitted from an active layer 103 and having a wavelength of, for example, 470 nm to be reflected from the bumps 111 and then to be taken out to the outside through the substrate 101. Accordingly, the light-emitting diode of the second prior art can emit light with high luminance. Furthermore, the use of the submount 113 with the protection diode increases the electrostatic breakdown voltage.

However, since any of the light-emitting diodes of the first and second prior arts is formed on the substrate 110 of sapphire, which has a relatively low thermal conductivity and exhibits poor heat radiation, there arises a problem of a low limit point of high-output operation.

In addition, sapphire is an insulating material and exhibits a low electrostatic breakdown voltage. Thus, there arises another problem that the cost of packaging increases, for example, in the case where a protection diode against surges is needed as in the second prior art.

Moreover, the substrate 101 has no conductivity, and thus the light-emitting diodes can be in only one structure in which n- and p-side electrodes are formed on the same surface (upper surface) of the substrate 101 and cannot be in a structure in which these electrodes face each other with the substrate 101 sandwiched therebetween. As a result, the series resistance as a diode increases, thus increasing the operating voltage.

### SUMMARY OF THE INVENTION

It is therefore an object of the present invention to achieve excellent heat radiation and increased electrostatic breakdown voltage in a semiconductor light-emitting device of a compound semiconductor, especially a GAN-based semiconductor. Other objects are improving the luminous efficacy and reducing the series resistance in the device.

In order to achieve these objects, according to the present invention, a semiconductor light-emitting device has a configuration in which opposed electrodes are formed on the front and back faces of a semiconductor multilayer film of a compound semiconductor including an active layer and in which a relatively thick metal film is provided on one of the opposed electrodes. In addition, one of the electrodes that is in contact with the metal film is made of a material having a high reflectance with respect to light emitted from the active layer, and the other is made of a transparent material or is made to have a plane size as small as possible.

Specifically, an inventive semiconductor light-emitting device includes: a semiconductor multilayer film including at least two semiconductor layers having mutually different conductivity types; a first electrode formed on a surface of the semiconductor multilayer film; a second electrode formed on the opposite surface of the semiconductor multilayer film; and a metal film formed to be in contact with one of the first and second electrodes and having a thickness greater than or equal to that of the semiconductor multilayer film.

In the inventive semiconductor light-emitting device, a substrate on which the semiconductor multilayer film has been grown is removed, and the metal film having a thickness greater than or equal to that of the semiconductor multilayer film is provided instead. Then, it is possible to suppress light absorption in the substrate that occurs in the case where the substrate remains. As a result, it is possible to extract more emission of light from the surface of the semiconductor multilayer film opposite to the metal film. In addition, the substrate is removed and a relatively thick metal film is provided instead. Accordingly, the series resistance is reduced, the heat radiation is greatly improved, and the electrostatic breakdown voltage is increased. Moreover, reflection of light from the metal film can increase the luminous efficacy.

In the inventive semiconductor light-emitting device, the semiconductor multilayer film is preferably made of a Group III-V compound semiconductor containing nitrogen as a Group V element. Then, the removal of the different-material substrate produces an extremely high effect, because Group III-V compound semiconductor containing nitrogen as a Group V element, e.g., Group III-V nitride semiconductors, often use a different-material substrate such as a sapphire substrate.

In the inventive semiconductor light-emitting device, the metal film preferably has a thickness of 10 μm or more.

In the inventive semiconductor light-emitting device, the metal film is preferably made of gold, copper or silver.

In the inventive semiconductor light-emitting device, the metal film is preferably made of plating. Then, the metal film can be formed in a short time with excellent reproducibility. Accordingly, the semiconductor light-emitting device can be fabricated at low cost.

In the inventive semiconductor light-emitting device, the metal film preferably includes a metal layer located at the side thereof opposite to the semiconductor multilayer film and having a melting point of 300° C. or less. Then, in dice bonding of the semiconductor light-emitting device on a package or a lead frame, the metal layer having a melting point of 300° C. or less serves as a solder member, so that it is not necessary to additionally use a solder member.

In this case, the metal layer preferably contains tin.

In the inventive semiconductor light-emitting device, said one of the first and second electrodes that is in contact with the metal film preferably has a reflectance of 90% or higher with respect to light emitted from the semiconductor multilayer film. Then, the light extraction efficiency is improved, thus increasing the luminance of the light-emitting device.

In the inventive semiconductor light-emitting device, said one of the first and second electrodes that is in contact with the metal film is preferably formed out of a single layer made of at least one material selected from the group consisting of gold, platinum, copper, silver and rhodium or a multilayer film including at least two of these materials.

The inventive semiconductor light-emitting device preferably includes a mirror structure formed between the semiconductor multilayer film and the metal film and made of a dielectric or a semiconductor. In this device, the mirror structure preferably has a reflectance of 90% or higher with respect to light emitted from the semiconductor multilayer film. Then, the mirror structure has high light extraction efficiency, as compared to an electrode having a high reflectance and made of a single material. Accordingly, the luminance of the light-emitting device can be increased.

In this case, the mirror structure preferably contains one of silicon oxide, titanium oxide, niobium oxide, tantalum oxide and hafnium oxide or aluminum gallium indium nitride (AlₓGa_{y}In_{1-x-y}N) (where 0≦x, y≦1 and 0≦x+y≦1) and is preferably formed to have a refractive index varying cyclically with respect to the wavelength of the light emitted from the semiconductor multilayer film.

In the inventive semiconductor light-emitting device, one of the first and second electrodes provided on the surface of the semiconductor multilayer film opposite to the metal film is preferably transparent.

In the inventive semiconductor light-emitting device, one of the first and second electrodes provided on the surface of the semiconductor multilayer film opposite to the metal film is preferably made of indium tin oxide or a metal containing nickel and having a thickness of 20 nm or less.

The inventive semiconductor light-emitting device preferably includes a current-confinement film which is made of a dielectric and is formed between the semiconductor multilayer film and the metal film at the peripheries of the semiconductor multilayer film and the metal film.

An inventive method for fabricating a semiconductor light-emitting device includes the steps of a) forming, on a substrate of a single crystal, a semiconductor multilayer film including at least two semiconductor layers having mutually different conductivity types; b) separating the substrate from the semiconductor multilayer film; c) forming a first electrode on a surface of the semiconductor multilayer film and forming a second electrode on the opposite surface of the semiconductor multilayer film; and d) forming a metal film over one of the first and second electrodes.

With the inventive method for fabricating a semiconductor light-emitting device, the substrate on which the semiconductor multilayer film has been formed is removed from the semiconductor multilayer film, so that absorption of light in the substrate is suppressed. Accordingly, it is possible to extract more emission of light from the surface of the semiconductor multilayer film opposite to the metal film. In addition, instead of the substrate, the metal film is provided with the electrode provided on the semiconductor multilayer film and sandwiched between the semiconductor multilayer film and the metal film. Accordingly, the series resistance at the semiconductor multilayer film is reduced, the heat radiation is greatly improved, and the electrostatic breakdown voltage is increased.

In the inventive method for fabricating a semiconductor light-emitting device, the semiconductor multilayer film is preferably made of a Group III-V compound semiconductor containing nitrogen as a Group V element.

In the inventive method for fabricating a semiconductor light-emitting device, in the step b), irradiating light having a wavelength at which the light passes through the substrate and is absorbed in part of the semiconductor multilayer film is preferably applied onto the surface of the substrate opposite to the semiconductor multilayer film, so that a decomposition layer is formed inside the semiconductor multilayer film by decomposition of part of the semiconductor multilayer film, thereby separating the substrate from the semiconductor multilayer film. Then, even if the substrate has a relatively large area, the substrate can be separated from the semiconductor multilayer film with high reproducibility.

In the inventive method for fabricating a semiconductor light-emitting device, in the step b), the substrate is preferably removed by polishing, thereby separating the substrate from the semiconductor multilayer film. Then, even if the substrate has a relatively large area, the substrate can be separated from the semiconductor multilayer film at low cost.

In the inventive method for fabricating a semiconductor light-emitting device, the step a) preferably includes the steps of: partially forming the semiconductor multilayer film, and then applying irradiating light, having a wavelength at which the light passes through the substrate and is absorbed in the semiconductor multilayer film, onto the surface of the substrate opposite to the semiconductor multilayer film, thereby decomposing part of the semiconductor multilayer film to form a decomposition layer inside the partially formed semiconductor multilayer film; and forming the rest of the semiconductor multilayer film on the partially formed semiconductor multilayer film, after the decomposition layer has been formed. Then, the semiconductor multilayer film and the substrate are loosely bonded together with the decomposition layer sandwiched therebetween. Accordingly, in the case where the rest of the semiconductor multilayer film includes, for example, a device structure (e.g., active layer), the formation of the rest of the semiconductor multilayer film over the partially formed semiconductor multilayer film after the formation of the decomposition film has the device structure less liable to be affected by the difference in thermal expansion coefficient or lattice mismatch between the substrate and the semiconductor multilayer film. As a result, the device structure has excellent crystallinity.

The irradiating light applied to the substrate is preferably pulsing laser light beam. Alternatively, the irradiating light is preferably an emission line of a mercury lamp. Then, in the case of a pulsing laser light beam used as a light source, the output power of the light beam is remarkably increased, thus easily separating the semiconductor multilayer film. In addition, in the case of the emission line of a mercury lamp used as a light source, the power of the output light is inferior to that of the laser light beam, but the spot size can be enlarged, so that the throughput in the step of applying light can be improved.

The irradiating light is preferably applied such that the substrate is scanned within the surface thereof. Then, even if the substrate has a relatively large area, the substrate can be separated from the semiconductor multilayer film without being affected by the beam size of the light source.

The irradiating light is preferably applied, while heating the substrate.

The inventive method for fabricating a semiconductor light-emitting device preferably includes the step e) of forming another multilayer film made of a dielectric or a semiconductor on the semiconductor multilayer film, and then patterning said another multilayer film, between the steps a) and b), wherein in the step c), one of the first and second electrodes is preferably formed on the patterned multilayer film, and in the step d), the metal film is preferably formed on the electrode formed on the patterned multilayer film.

In this case, in the step c), the other one of the first and second electrodes is preferably formed on the surface of the semiconductor multilayer film opposite to the multilayer film after the substrate has been separated from the semiconductor multilayer film.

The inventive method for fabricating a semiconductor light-emitting device preferably includes the steps of: f) bonding a first supporting member in film form for supporting the semiconductor multilayer film onto the semiconductor multilayer film, the first supporting member being made of a material different from a material constituting the semiconductor multilayer film, between the steps of a) and b); and g) peeling off the first supporting member from the semiconductor multilayer film, after the step b) has been performed. Then, it is possible to prevent a crack from occurring in the semiconductor multilayer film during a process step for reducing stress caused in the semiconductor multilayer film because of the formation of a decomposition layer in part of the semiconductor multilayer film. As a result, even if the substrate has a relatively large area, it is possible to separate the substrate from the semiconductor multilayer film without creating any crack.

In this case, the inventive method for fabricating a semiconductor light-emitting device preferably includes the steps of: h) bonding a second supporting member in film form having different properties from those of the first supporting member onto the surface of the semiconductor multilayer film opposite to the first supporting member, before the step g) is performed; and i) peeling off the second supporting member from the semiconductor multilayer film, after the step g) has been performed.

In this case, the first or second supporting member is preferably a polymer film, a single-crystal substrate made of a semiconductor, or a metal plate. Then, in the case of a polymer film or a metal plate, an excellent plasticity is exhibited, and in the case of a single-crystal substrate of a semiconductor, an excellent cleavage can be performed. Accordingly, the substrate can be separated more easily.

In this case, the polymer film is preferably provided, at a bonding surface thereof, with an adhesive layer that can be peeled off when heated.

The inventive method for fabricating a semiconductor light-emitting device preferably includes the step i) of selectively forming a current-confinement film of a dielectric on the semiconductor multilayer film, before the step c) is performed.

An inventive method for bonding a semiconductor light-emitting device includes the steps of a) forming, on a substrate of a single crystal, a semiconductor multilayer film including at least two semiconductor layers having mutually different conductivity types; b) bonding a supporting member in film form for supporting the semiconductor multilayer film onto the semiconductor multilayer film, the supporting member being made of a material different from a material constituting the semiconductor multilayer film; and c) dicing the semiconductor multilayer film and the supporting member together, thereby forming a plurality of chips which are supported by the supporting member having been divided into respective pieces; and d) performing dice bonding on the chips supported by the supporting member, and then peeling off the supporting member from the chips.

With the inventive method for bonding a semiconductor light-emitting device, even if the semiconductor multilayer film is extremely thin, e.g., as thin as several μm or less, dice bonding can be performed with a supporting member in film form bonded to the semiconductor multilayer film. Accordingly, an extremely thin semiconductor light-emitting device can be bonded.

In the inventive method for bonding a semiconductor light-emitting device, the supporting member is preferably a polymer film.

In the inventive method for bonding a semiconductor light-emitting device, the polymer film is preferably provided with, at a bonding surface thereof, an adhesive layer which can be peeled off when heated.

### BRIEF DESCRIPTION OF THE DRAWINGS

FIG. 1 is a structural cross-sectional view showing a semiconductor light-emitting device according to a first embodiment of the present invention.

FIGS. 2A through 2D are structural cross-sectional views showing respective process steps of a method for fabricating the semiconductor light-emitting device of the first embodiment.

FIGS. 3A through 3D are structural cross-sectional views showing respective process steps of the method for fabricating the semiconductor light-emitting device of the first embodiment.

FIG. 4 is a structural cross-sectional view showing a semiconductor light-emitting device according to a second embodiment of the present invention.

FIGS. 5A through 5C are structural cross-sectional views showing respective process steps of a method for fabricating the semiconductor light-emitting device of the second embodiment.

FIGS. 6A through 6C are structural cross-sectional views showing respective process steps of the method for fabricating the semiconductor light-emitting device of the second embodiment.

FIGS. 7A through 7C are structural cross-sectional views showing respective process steps of a method for fabricating the semiconductor light-emitting device of the second embodiment.

FIGS. 8A through 8C show a light-emitting diode according to a modified example of the second embodiment. FIG. 8A is a structural cross-sectional view, FIG. 8B shows a micrograph of a chip surface using an SEM, and FIG. 8C is a photograph of a chip surface in the state of light emission.

FIG. 9 is a graph showing emission spectra of a semiconductor light-emitting device according to the modified example of the second embodiment.

FIG. 10 is a structural cross-sectional view showing a semiconductor light-emitting device according to a third embodiment of the present invention.

FIGS. 11A through 11C are structural cross-sectional views showing respective process steps of a method for fabricating the semiconductor light-emitting device of the third embodiment.

FIGS. 12A through 12C are structural cross-sectional views showing respective process steps of the method for fabricating the semiconductor light-emitting device of the third embodiment.

FIGS. 13A through 13C are structural cross-sectional views showing respective process steps of a method for fabricating the semiconductor light-emitting device of the third embodiment.

FIG. 14 is a structural cross-sectional view showing a semiconductor light-emitting device according to a fourth embodiment of the present invention.

FIGS. 15A through 15C are structural cross-sectional views showing respective process steps of a method for fabricating the semiconductor light-emitting device of the fourth embodiment.

FIGS. 16A through 16C are structural cross-sectional views showing respective process steps of the method for fabricating the semiconductor light-emitting device of the fourth embodiment.

FIGS. 17A through 17C are structural cross-sectional views showing respective process steps of a method for fabricating the semiconductor light-emitting device of the fourth embodiment.

FIG. 18 is a structural cross-sectional view showing a light-emitting diode according to a first prior art.

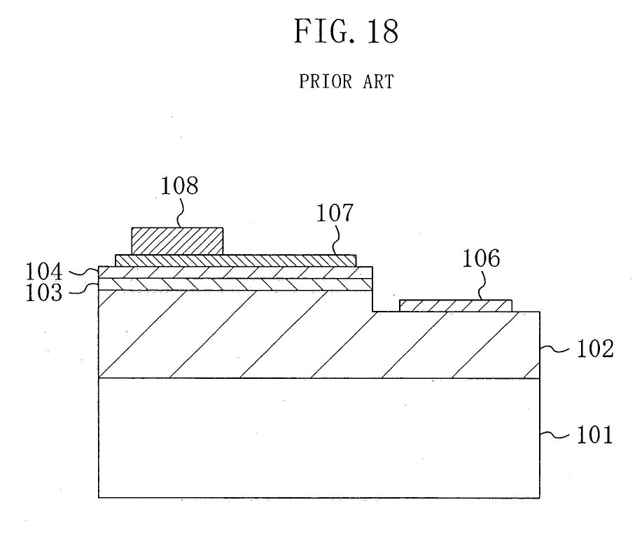

FIG. 19 is a structural cross-sectional view showing a light-emitting diode according to a second prior art.

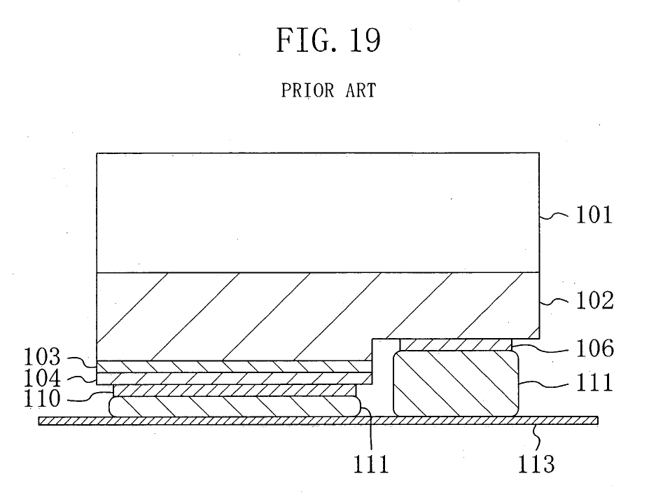

### DESCRIPTION OF THE PREFERRED EMBODIMENTS

Embodiment 1

A first embodiment of the present invention will be described with reference to the drawings.

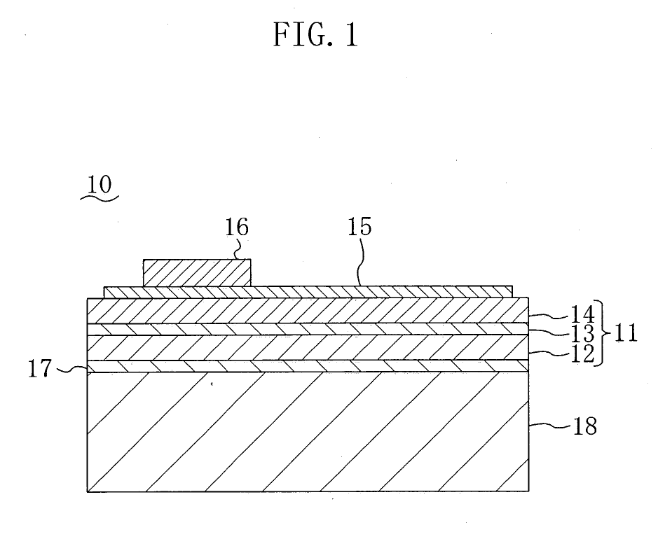

FIG. 1 shows a cross-sectional structure of a light-emitting diode which is a semiconductor light-emitting device according to the first embodiment and is capable of emitting short-wavelength light such as blue or green light.

As shown in FIG. 1, a light-emitting diode 10 according to the first embodiment has an element structure 11 including a plurality of semiconductor layers.

A transparent p-side electrode 15 made of an oxide containing indium (In) and tin (Sn), i.e., ITO, is formed on the element structure 11. A bonding pad 16 of gold (Au) is formed on a region of the p-side electrode 15. An n-side electrode 17 as a stack of titanium (Ti) and gold (Au) is formed on the surface of the element structure 11 opposite to the p-side electrode 15.

The element structure 11 includes: an n-type semiconductor layer 12 of n-type aluminum gallium nitride (AlGaN); an active layer 13 of indium gallium nitride (InGaN) formed on the n-type semiconductor layer 12; and a p-type semiconductor layer 14 of p-type aluminum gallium nitride (AlGaN) formed on the active layer 13. In this case, the active layer 13 may have a quantum well structure, for example. The emission of blue light with a wavelength of, for example, 470 nm generated in the active layer 13 is reflected from the n-side electrode 17 of Ti/Au and is taken out to the outside through the p-side electrode 15 of ITO.

The first embodiment is characterized in that a metal film 18 of gold plating a with a thickness of about 50 μm is formed using an Au layer of the n-side electrode 17 opposite to the n-type semiconductor layer 12 (i.e., the lowermost Au layer of the n-side electrode 17) as an underlying layer.

In this manner, in the first embodiment, the metal n-side electrode 17 is formed on the n-type semiconductor layer 12 of the element structure 11, which constitutes the light-emitting diode 10, such that the n-side electrode 17 has a reflectance of 90% or higher with respect to light emitted from the active layer 13. In this way, the light emitted from the active layer 13 is reflected from the n-side electrode 17 and is taken out through the transparent p-side electrode 15, thereby greatly increasing the light extraction efficiency.

In addition, instead of a substrate made of a single crystal, the metal film 18 of Au is provided on the surface of the n-side electrode 17 opposite to the element structure 11. Accordingly, heat generated in the active layer 13 is released to the outside via the metal film 18. By thus providing the metal film 18 replacing a single-crystal substrate to grow the element structure 11 of GaN-based semiconductors thereon, heat radiation from the element structure 11 improves significantly, thus ensuring high-output operation of the light-emitting diode 10 of this embodiment. Further, since the light-emitting device 10 includes no insulating substrate such as a sapphire substrate, resistance to electrostatic breakdown enhances.

It is sufficient for the metal film 18 to have a thickness of 10 μm or more. The metal film 18 is not necessarily made of gold (Au) so long as the metal film 18 is made of a material with high thermal conductivity such as copper (Cu) or silver (Ag) or an alloy of these materials.

The n-side electrode 17 that is in contact with the metal film 18 does not necessarily have a multilayer structure of titanium (Ti) and gold (Au). Alternatively, the n-side electrode 17 may be a single film made of at least one material selected from the group consisting of gold (Au), platinum (Pt), copper (Cu), silver (Ag) and rhodium (Rh) or may be in a multilayer structure containing at least two of these materials.

The transparent p-side electrode 15 is not necessarily made of ITO but may be a stack of nickel (Ni) and gold (Au) with a total thickness of 20 nm or less.

Hereinafter, a method for fabricating the light-emitting diode 10 thus configured will be described with reference to the drawings.

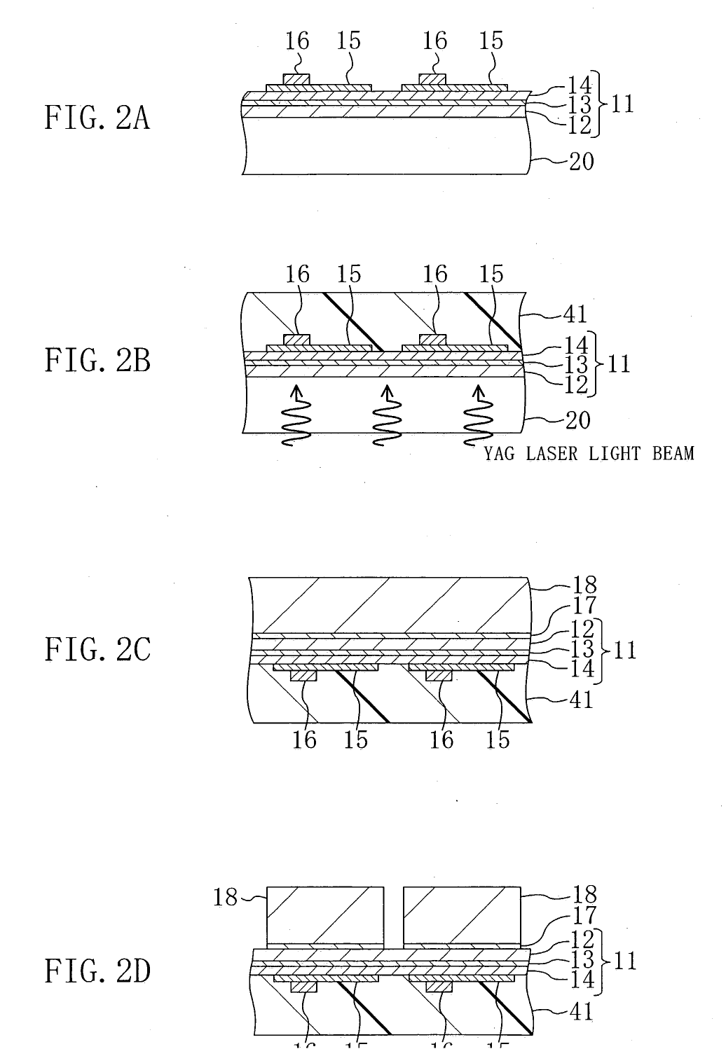

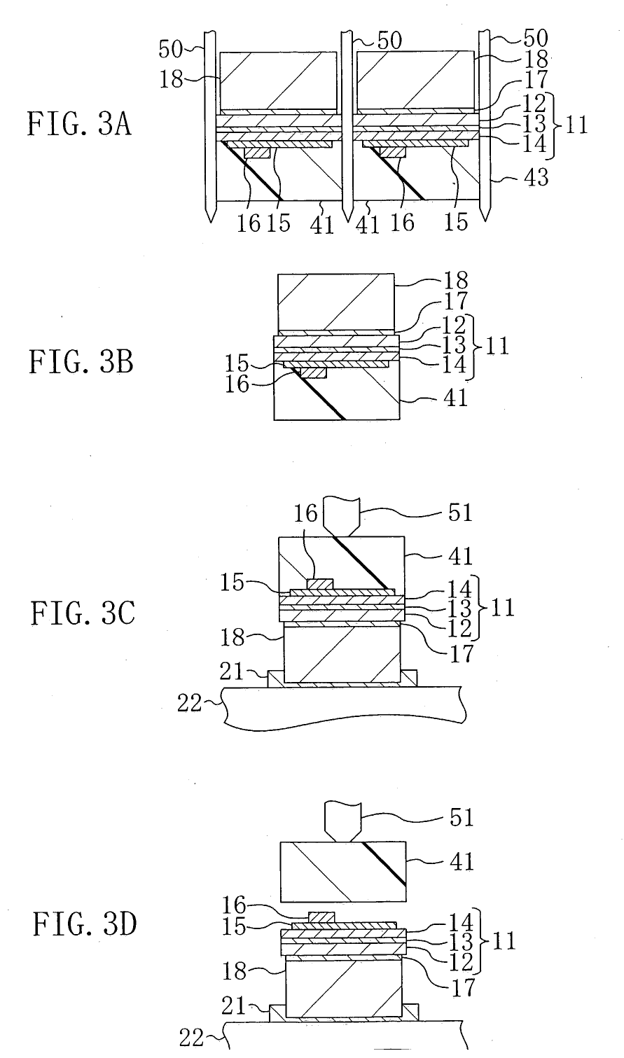

FIGS. 2A through 2D and FIGS. 3A through 3D show cross-sectional structures in respective process steps of a method for fabricating a light-emitting diode according to the first embodiment.

First, as shown in FIG. 2A, an n-type semiconductor layer 12 of n-type AlGaN, an active layer 13 of InGaN and a p-type semiconductor layer 14 of p-type AlGaN are grown in this order by, for example, a metal organic chemical vapor deposition (MOCVD) process over the principal surface of a substrate 20 made of sapphire (single-crystal Al₂O₃) in wafer state, thereby forming an element structure 11 including the n-type semiconductor layer 12, active layer 13 and p-type semiconductor layer 14.

In this case, the element structure 11 preferably has a configuration including: a buffer layer and an n-type contact layer provided between the substrate 20 and the n-type semiconductor layer (n-type cladding layer) 12; the active layer 13 having a quantum well structure; and a p-type contact layer provided on the p-type semiconductor layer (p-type cladding layer) 14.

TABLE 1

| name | composition | thickness |
|---|---|---|
| p-type contact layer | p-GaN | 0.5 μm |
| p-type cladding layer | p-Al_{0.1}Ga_{0.9}N | 100 nm |
| (p-type semiconductor layer) | | |
| active layer | In_{0.35}Ga_{0.65}N | 2 nm |
| n-type cladding layer | n-Al_{0.1}Ga_{0.9}N | 100 nm |
| (n-type semiconductor layer) | | |
| n-type contact layer | n-GaN | 3 μm |
| buffer layer | GaN | 30 nm |
| substrate | sapphire | — |

In Table 1, as publicly known, the buffer layer of GaN formed on the substrate 20 reduces a lattice mismatch caused between the substrate 20 and an epitaxial layer such as the n-type contact layer grown on the buffer layer, at a relatively low substrate temperature of, for example, 550° C. In growing the epitaxial layer such as the n-type semiconductor layer 12, the substrate temperature is set at about 1020° C. Silicon (Si) using silane (SiH₄) is used as an n-type dopant, and magnesium (Mg) using bis-cyclopentadienyl magnesium (Cp₂Mg) is used as a p-type dopant.

Thereafter, an ITO film is deposited by, for example, an RF sputtering process over the element structure 11, and the deposited ITO film is patterned, thereby forming p-side electrodes 15. Then, an electrode film of Au is evaporated and deposited by, for example, an electron beam evaporation process onto the p-side electrodes 15, and the evaporated and deposited electrode film is patterned so as to cover respective parts of the p-side electrodes 15, thereby forming bonding pads 16 out of the electrode film. In this case, the electrode film preferably has a thickness of 500 nm or more. The ITO film and the electrode film may be patterned at a time.

Next, as shown in FIG. 2B, a supporting member in film form exhibiting excellent plasticity, e.g., a supporting film 41 of a polymer film with a thickness of about 100 μm, is bonded onto the element structure 11 provided with the p-side electrodes 15 and the bonding pads 16. In this case, a polymer film of, for example, polyester having, at its supporting face, an adhesive layer which foams to lose its adhesive power when heated is used as the supporting film 41. The use of such a supporting film 41 prevents a problem of the occurrence of, for example, an electrical contact failure caused when the adhesive layer remains on the element structure 11 after the supporting film 41 has been peeled off in a subsequent process step. Subsequently, the surface of the substrate 20 opposite to the element structure 11 is irradiated with a pulsing YAG (yttrium, aluminum and garnet) laser third-harmonic light beam with a wavelength of 355 nm such that the substrate 20 is scanned. The applied laser light beam is not absorbed in the substrate 20 but is absorbed in the element structure 11, i.e., the n-type semiconductor layer 12. This light absorption causes the n-type semiconductor layer 12 to generate heat locally, so that the bonding of atoms is cut off at the interface between the n-type semiconductor layer 12 and the substrate 20, thereby forming a thermal decomposition layer (not shown) containing metal gallium (Ga) between the substrate 20 and the n-type semiconductor layer 12. That is to say, with the application of the laser light beam to the n-type semiconductor layer 12, the n-type semiconductor layer 12 grown on the substrate 20 is bonded to the substrate 20 via the thermal decomposition layer, while the bonding of atoms is cut off between the n-type semiconductor layer 12 and the substrate 20. The light source for the laser light beam to be applied is not limited to the YAG laser third-harmonic light beam and may be a KrF excimer laser light beam with a wavelength of 248 nm. In such a case, KrF is a gas mixture of krypton and fluorine used in an eximer laser. Instead of these sources for laser light beam, an emission line of a mercury lamp with a wavelength of 365 nm may be used. In the case where the emission line of the mercury lamp is used, the power of the output light is inferior to that of the laser light beam, but the spot size can be enlarged, so that the period of time required for the irradiation can be shortened in the step of separating the substrate 20.

Then, as shown in FIG. 2C, the thermal decomposition layer is dissolved by wet etching using, for example, hydrochloric acid (HCl), thereby separating and removing the substrate 20 from the element structure 11. Examples of methods for separating the substrate 20 also include a method of removing the substrate 20 by a chemical mechanical polishing process, as well as the method of forming a thermal decomposition film with light application and dissolving the thermal decomposition film.

Thereafter, an n-side electrode 17 of Ti/Au is formed by, for example, an electron beam evaporation process on the surface of the n-type semiconductor layer 12 in the element structure 11, from which the substrate 20 has been removed, opposite to the active layer 13. Subsequently, a metal film 18 is deposited by a gold plating process to a thickness of about 50 μm over the n-side electrode 17, using an Au layer in the n-side electrode 17 as an underlying layer.

Then, as shown in FIG. 2D, respective parts of the metal film 18 and the n-side electrode 17 associated with a chip-dividing region of the element structure 11 are selectively etched, thereby exposing a chip-dividing region of the n-type semiconductor layer 12. In the first embodiment, the step of separating the substrate 20, the steps of depositing the n-side electrode 17 and the metal film 18 and the step of etching the n-side electrode 17 and the metal film 18 are performed with the supporting film 41 provided on the surface of the element structure 11 opposite to the substrate 20. Accordingly, even if the element structure 11 is extremely thin, for example, about 5 μm, these steps can be performed without creating any problem.

Next, as shown in FIG. 3A, an exposed region (dicing region) of the element structure 11, which is supported by the supporting film 41, exposed from the metal film 18 is cut off with a dicing blade 50. At this time, the supporting film 41 is also cut simultaneously. In this manner, as shown in FIG. 3B, a light-emitting diode chip in which the relatively thick metal film 18 is provided on the n-side electrode 17 and the supporting film 41 is bonded to the p-side electrode 15 and which measures, for example, 300 μm per side, is obtained.

Thereafter, as shown in FIG. 3C, the supporting film 41 having been divided into a chip is vacuum-adhered to a collet 51 along the upper surface of the supporting film 41, and the chips is bonded into mounting position on a package 22 by means of a solder member 21 made of lead (Pb) and zinc (Zn).

Then, as shown in FIG. 3D, the chip is heated to about 200° C., for example, during the bonding, so that the adhesive applied to the supporting film 41 loses its adhesive power because the adhesive has the property of foaming when heated. Accordingly, the supporting film 41 can be easily peeled off from the element structure 11 using the collet 51.

In this manner, in the first embodiment, the dice bonding is performed with the supporting film 41, which is easily peeled off with heat, adhered to the element structure 11. Accordingly, even if the element structure 11 in the chip has a thickness of about 50 μm, the dice bonding can be easily conducted as intended.

If an alloy plating of gold (Au) and tin (Sn) whose melting point is about 280° C., for example, is provided at least in a lower part of the metal film 18, the solder member 21 is not needed any more.

As described above, according to the fabrication method of the first embodiment, it is possible to obtain the light-emitting diode 10 that exhibits high luminance, excellent heat radiation and high resistance to electrostatic breakdown and that has low series resistance

Modified Example of Fabrication Method

In the first embodiment, the thermal decomposition layer containing metal gallium is formed between the substrate 20 and the element structure 11 by applying laser light beam, after the fabrication of the element structure 11. However, the present invention is not limited to this specific embodiment and may use the following fabrication method.

Specifically, an underlying layer of a GaN-based semiconductor is formed on the substrate 20 and then light is applied thereto so that a thermal decomposition layer is formed between the substrate 20 and the underlying layer. Subsequently, the element structure 11 is grown again on the underlying layer under which the thermal decomposition layer has been formed.

In this manner, the element structure 11 is grown with the thermal decomposition layer having no crystal structure grown on the underlying layer so that the thermal decomposition layer is interposed between the underlying layer and the substrate 20. Therefore, the underlying layer and the element structure 11 of GaN-based semiconductors are less susceptible to the influence of the difference in thermal expansion coefficient between the underlying layer or element structure 11 and the substrate 20. As a result, the crystallinity of the element structure 11 improves as well as the occurrence of defects such as a crack or a crystal defect is reduced.

In order to separate and remove the substrate 20 from the underlying layer, the underlying layer may be irradiated with, for example, a laser light beam again, or the thermal decomposition layer may be etched with, for example, HCl.

Embodiment 2

A second embodiment of the present invention will be described with reference to the drawings.

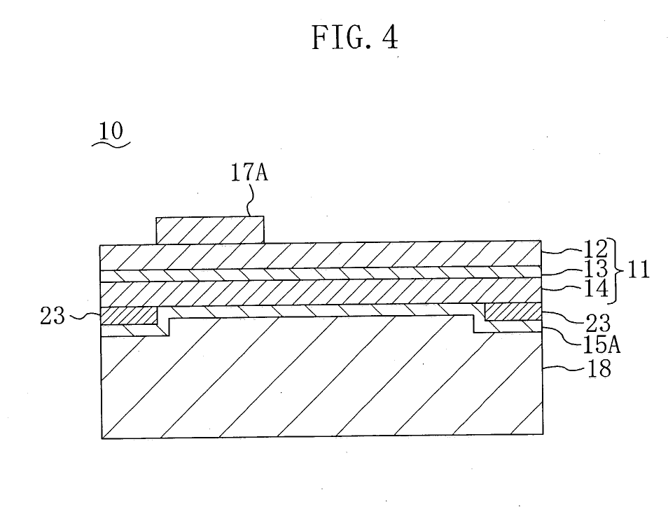

FIG. 4 shows a cross-sectional structure of a light-emitting diode which is a semiconductor light-emitting device according to the second embodiment and is capable of emitting short-wavelength light such as blue or green light. In FIG. 4, each member already shown in FIG. 1 is identified by the same reference numeral and the description thereof will be omitted herein.

As shown in FIG. 4, in a light-emitting diode 10 according to the second embodiment, an n-side electrode 17A as a stack of titanium (Ti) and aluminum (Al) is selectively formed on the surface of an n-type semiconductor layer 12, which constitutes an element structure 11, opposite to an active layer 13 (i.e., on the upper surface of the semiconductor layer 12), and the n-side electrode 17A serves as a bonding pad. A p-side electrode 15A as a stack of platinum (Pt) and gold (Au) is formed on the side of the p-type semiconductor layer 14 opposite to the active layer 13 (i.e., lower side of the p-type semiconductor layer 14) so as to have a reflectance of 90% or higher with respect to light emitted from the active layer 13. A metal film 18 coated with gold plating having a thickness of about 50 μm is formed using the outermost Au layer of the p-side electrode 15A as an underlying layer.

The second embodiment is characterized in that a current-confinement film 23 of, for example, silicon dioxide (SiO₂) is provided between the p-type semiconductor layer 14 and the p-side electrode 15A at the periphery of the element structure 11. This reduces leakage current leaking along the side surfaces of the element structure 11, thus enhancing the luminous efficacy of the light-emitting device.

As described above, in the second embodiment, the metal p-side electrode 15A is formed on the lower side of the element structure 11 constituting the light-emitting diode 10 so as to have a reflectance of 90% or higher with respect to light emitted from the active layer 13. In this manner, the light emitted from the active layer 13 is reflected from the p-side electrode 15A and is taken out through a portion of the n-type semiconductor layer 12 where the n-side electrode 17A is not provided, thus greatly enhancing the light extraction efficiency.

In addition, the metal film 18 is provided on the surface of the p-side electrode 15A opposite to the element structure 11 (i.e., lower surface of the p-side electrode 15A), instead of a substrate of a single crystal. Accordingly, heat generated in the active layer 13 is released to the outside via the metal film 18. By thus providing the metal film 18 replacing a single-crystal substrate to grow the element structure 11 of GaN-based semiconductors thereon, heat radiation improves significantly, thus allowing high-output operation of the light-emitting diode 10 of this embodiment. Further, resistance to electrostatic breakdown is enhanced.

The p-side electrode 15A that is in contact with the metal film 18 does not necessarily have a multilayer structure of platinum (Pt) and gold (Au). Alternatively, the p-side electrode 15A may be a single film made of at least one material selected from the group consisting of gold (Au), platinum (Pt), copper (Cu), silver (Ag) and rhodium (Rh) or may be in a multilayer structure containing at least two of these materials.

Hereinafter, a method for fabricating the light-emitting diode 10 thus configured will be described with reference to the drawings.

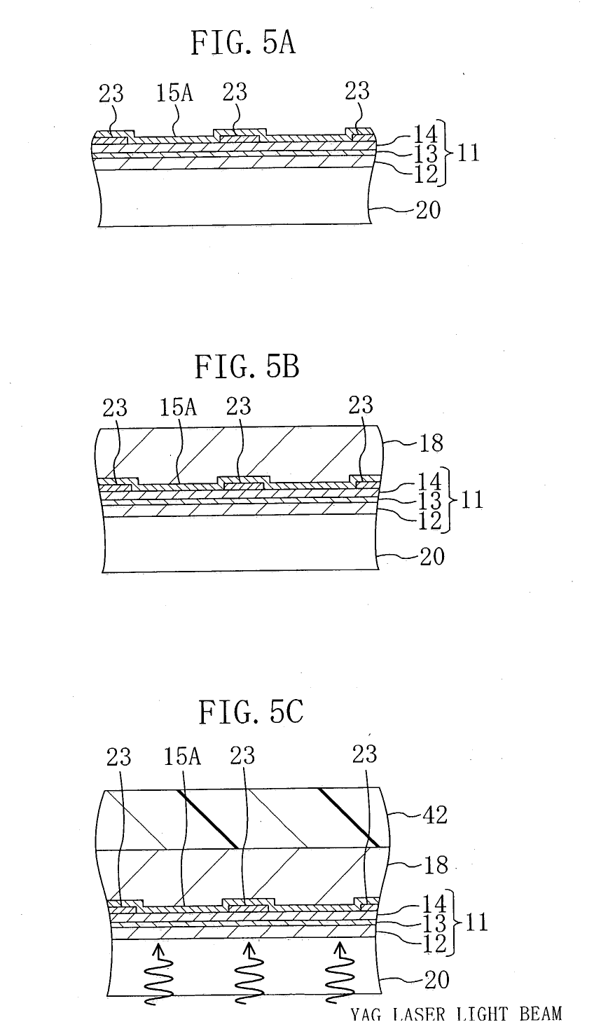

FIGS. 5A through 5C through FIGS. 7A through 7C show cross-sectional structures in respective process steps of a method for fabricating a light-emitting diode according to the second embodiment.

First, as shown in FIG. 5A, as in the first embodiment, an n-type semiconductor layer 12 of n-type AlGaN, an active layer 13 of InGaN and a p-type semiconductor layer 14 of p-type AlGaN are grown in this order by, for example, an MOCVD process over the principal surface of a substrate 20 made of sapphire in wafer state, thereby forming an element structure 11 including the n-type semiconductor layer 12, active layer 13 and p-type semiconductor layer 14.

Thereafter, a current-confinement film preform of silicon oxide is deposited by, for example, a vapor deposition (e.g., CVD) process to a thickness of about 300 nm over the element structure 11, i.e., the p-type semiconductor layer 14. Subsequently, the deposited current-confinement film preform is wet-etched using hydrofluoric acid (HF), for example, thereby forming a plurality of current-confinement films 23 with openings in which light-emitting regions of the element structure 11 are exposed, out of the current-confinement film preform. Thereafter, a p-side electrode 15A including a Pt layer with a thickness of about 50 nm and an Au layer with a thickness of about 200 nm is formed by an electron beam evaporation process on the entire surfaces of the current-confinement films 23 and the exposed regions of the p-type semiconductor layer 14 including exposed from the current-confinement films 23.

Next, as shown in FIG. 5B, a metal film 18 is deposited by a gold plating process to a thickness of about 50 μm over the p-side electrode 15A using an Au layer of the p-side electrode 15A as an underlying layer.

Then, as shown in FIG. 5C, a supporting member in film form exhibiting excellent plasticity, e.g., a first supporting film 42 of a polymer film with a thickness of, for example, about 100 μm, is bonded onto the metal film 18. In this case, a polymer film of, for example, polyester having, at its supporting face, an adhesive layer which foams to lose its adhesive power when heated at about 120° C. is used as the first supporting film 42. Subsequently, the surface of the substrate 20 opposite to the element structure 11 is irradiated with a pulsing YAG laser third-harmonic light beam with a wavelength of 355 nm such that the substrate 20 is scanned. As described above, the applied laser light beam is not absorbed in the substrate 20 but is absorbed in the element structure 11, i.e., the n-type semiconductor layer 12. This light absorption causes the n-type semiconductor layer 12 to generate heat locally, so that the bonding of atoms is cut off at the interface between the n-type semiconductor layer 12 and the substrate 20, thereby forming a thermal decomposition layer (not shown) containing metal gallium between the substrate 20 and the n-type semiconductor layer 12. The light source for the laser light beam to be applied is not limited to the YAG laser third-harmonic light beam and may be a KrF excimer laser light beam with a wavelength of 248 nm. Instead of these sources for laser light beam, an emission line of a mercury lamp with a wavelength of 365 nm may be used.

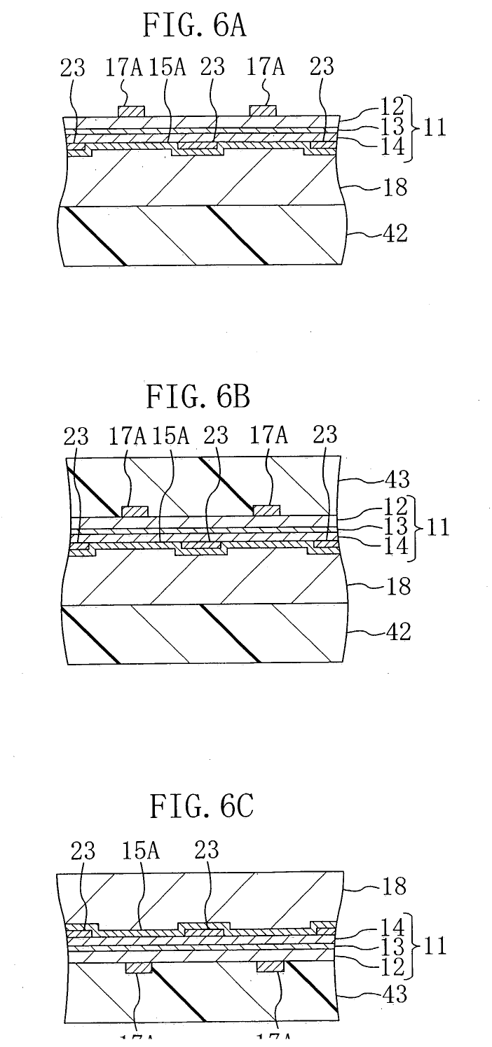

Thereafter, as shown in FIG. 6A, the thermal decomposition layer is dissolved by wet etching using, for example, hydrochloric acid, thereby separating and removing the substrate 20 from the element structure 11. Then, a multilayer film as a stack of Ti with a thickness of about 50 nm and Al with a thickness of about 800 nm is evaporated and deposited by, for example, an electron beam evaporation process onto the surface of the n-type semiconductor layer 12 of the element structure 11, from which the substrate 20 has been removed, opposite to the active layer 13. The evaporated and deposited multilayer film is patterned so as to cover partly the light-emitting regions of the element structure 11, thereby forming n-side electrodes 17A also serving as bonding pads, out of the multilayer film.

Subsequently, as shown in FIG. 6B, a second supporting film 43 of a polymer film with a thickness of, for example, about 100 μm, is bonded onto the n-type semiconductor layer 12 including the n-side electrodes 17A. As the second supporting film 43, a polymer film of, for example, polyester having, at its supporting face, an adhesive layer which foams to lose its adhesive power when heated at about 170° C. is used.

Then, the element structure 11 supported by the first and second supporting films 42 and 43 is heated to about 120° C. This heating at about 120° C. causes the adhesive layer provided in the first supporting film 42 to foam and to reduce its adhesive power between the first supporting film 42 and the metal film 18, so that the first supporting film 42 is easily separated from the metal film 18, as shown in FIG. 6C. At this time, there is no possibility that the adhesive of the first supporting film 42 remains on the surface of the metal film 18.

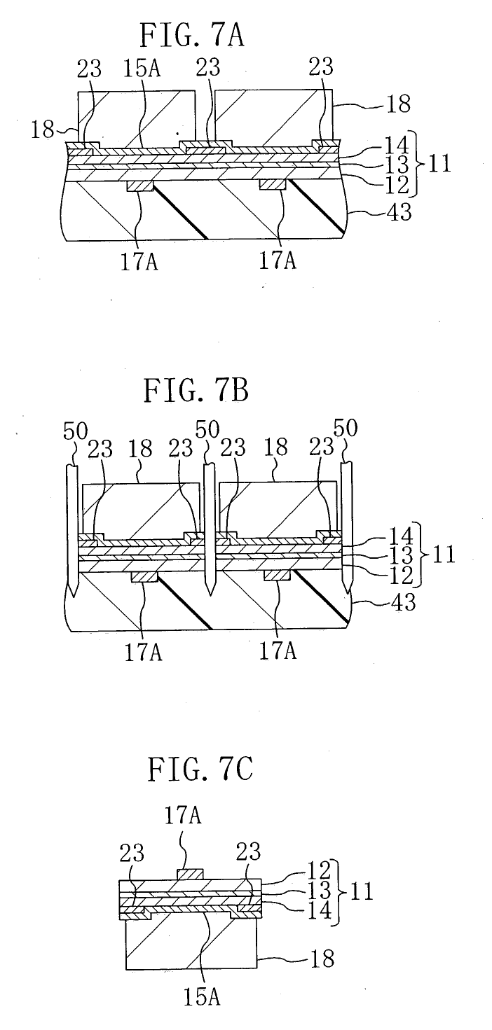

Then, as shown in FIG. 7A, part of the metal film 18 associated with a chip-dividing region of the element structure 11, i.e., part of the metal film 18 located over the current-confinement films 23, is selectively etched, thereby exposing a chip-dividing region of the p-side electrode 15A. In the second embodiment, the step of separating the substrate 20 and the steps of depositing respective films for the n-side electrode 17A are also performed with the first supporting film 42 provided on the element structure 11, and the step of etching the metal film 18 is also performed with the second supporting film 43 provided on the element structure 11. Accordingly, even if the element structure 11 is extremely thin, for example, about 5 μm, these steps can be performed without creating any problem.

Next, as shown in FIG. 7B, an exposed region (dicing region) of the p-side electrode 15A, which is supported by the second supporting film 43, exposed from the metal film 18 and respective parts located under the exposed region are cut off with a dicing blade 50. In this manner, a light-emitting diode chip which measures, for example, 300 μm per side in plane size is obtained, out of the element structure 11. In this case, the second supporting film 43 is cut halfway.

Then, as shown in FIG. 7C, the second supporting film 43 is heated to about 170° C. so that the adhesive layer provided in the second supporting film 43 foams and reduces its adhesive power between the second supporting film 43 and the chips, thereby easily separating the respective chips from the second supporting film 43. After this removal, the chips are bonded in a subsequent step for assembly such as dice bonding.

As described above, according to the fabrication method of the second embodiment, it is possible to obtain the light-emitting diode 10 that exhibits high luminance, excellent heat radiation and high resistance to electrostatic breakdown, and has low series resistance

Modified Example of Embodiment 2

Hereinafter, a modified example of the second embodiment will be described with reference to the drawings.

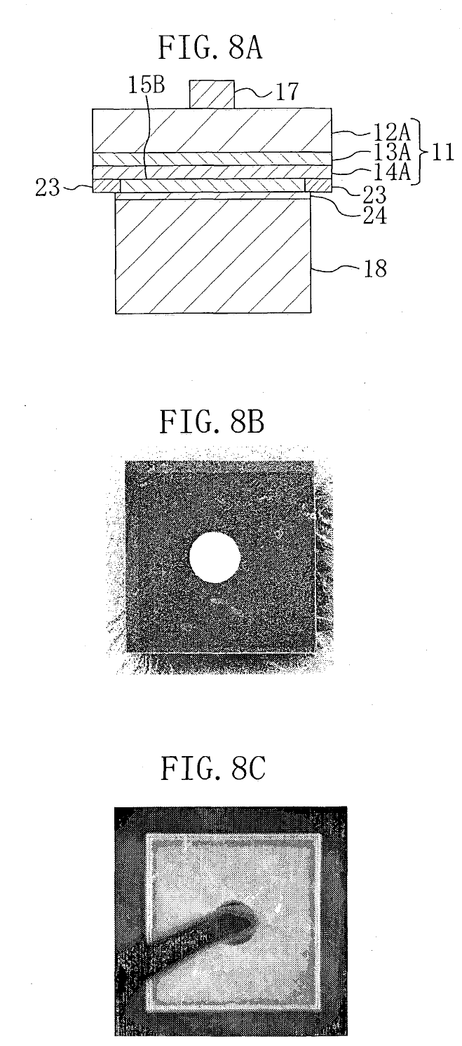

FIGS. 8A through 8C show a light-emitting diode according to the modified example of the second embodiment. FIG. 8A shows a cross-sectional structure of the diode, FIG. 8B shows a micrograph of a chip surface using a scanning electron microscope (SEM), and FIG. 8C is a photograph of a chip surface in the state of light emission. In FIG. 8A, each member already shown in FIG. 4 is identified by the same reference numeral and the description thereof will be omitted herein.

This modified example is an experimental example. As shown in FIG. 8A, n-type GaN is used for an n-type semiconductor layer 12A, an active layer 13A uses a multi-quantum well structure of InGaN, and p-type GaN is used for a p-type semiconductor layer 14A. The n-type semiconductor layer 12A, the active layer 13A and the p-type semiconductor layer 14A constitute an element structure 11. In this case, the chip measures 300 μm per side in plane size.

An n-side electrode 17 as a stack of Ti/Au is provided on a center portion of a light-emitting region of the n-type semiconductor layer 12A. Pt is used for a p-side electrode 15B, and a plating underlying layer 24 of Ti/Au is provided on the surface of the p-side electrode 15B opposite to the element structure 11.

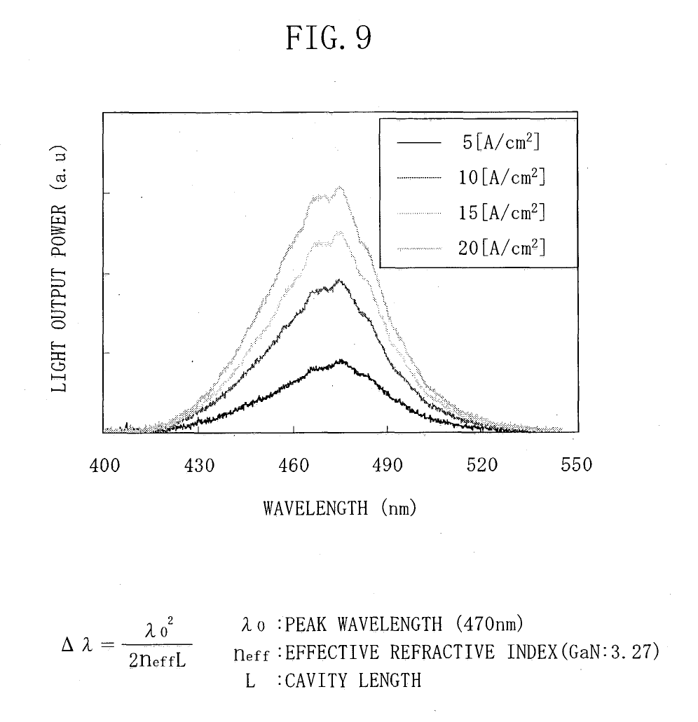

FIG. 9 shows a result of measurement on emission spectra of a light-emitting diode 10 according to this modified example. As shown in the graph of FIG. 9, as the operating current increases, there appear a lager number of peaks due to resonance produced vertically to the active layer 13A, i.e., a vertical cavity action.

Embodiment 3

A third embodiment of the present invention will be described with reference to the drawings.

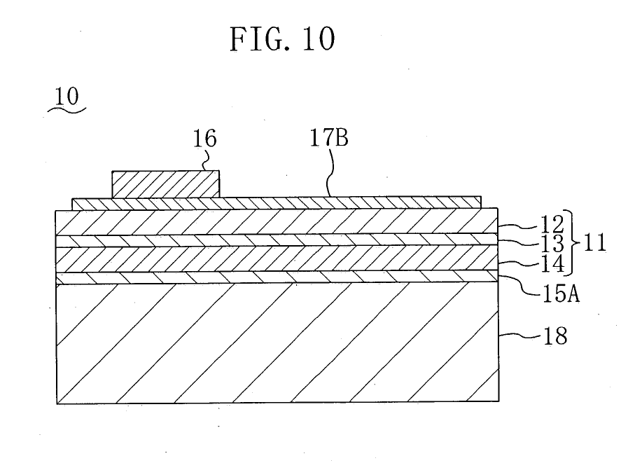

FIG. 10 shows a cross-sectional structure of a light-emitting diode which is a semiconductor light-emitting device according to the third embodiment and is capable of emitting short-wavelength light such as blue or green light. In FIG. 10, each member already shown in FIG. 4 is identified by the same reference numeral and the description thereof will be omitted herein.

An element structure 11 constituting the light-emitting diode of the third embodiment is provided with a transparent n-side electrode 17B of, for example, ITO on the surface of an n-type semiconductor layer 12 opposite to an active layer 13. A bonding pad 16 of Au is formed on a region of the n-side electrode 17B.

The active layer 13 may have a quantum well structure, for example. Emission of blue light produced in the active layer 13 and having a wavelength of 470 nm, for example, is reflected from a p-side electrode 15A of Pt/Au and is taken out to the outside through the n-side electrode 17B of ITO.

As described above, in the third embodiment, the metal p-side electrode 15A is formed on the lower side of the element structure 11 constituting the light-emitting diode 10 such that the p-side electrode 15A has a reflectance of 90% or higher with respect to light emitted from the active layer 13. In this manner, the light emitted from the active layer 13 is reflected from the p-side electrode 15A and is taken out through the transparent n-side electrode 17B provided on the n-type semiconductor layer 12, thus greatly enhancing the light extraction efficiency.

In addition, a metal film 18 is provided on the surface of the p-side electrode 15A opposite to the element structure 11 (i.e., lower surface of the p-side electrode 15A), instead of a substrate of a single crystal. Accordingly, heat generated in the active layer 13 is released to the outside via the metal film 18. By thus providing the metal film 18 replacing a single-crystal substrate to grow the element structure 11 of GaN-based semiconductors thereon, heat radiation improves significantly, thus allowing high-output operation of the light-emitting diode 10 of this embodiment. Further, since the light-emitting device 10 includes no insulating substrate such as a sapphire substrate, resistance to electrostatic breakdown is enhanced.

Hereinafter, a method for fabricating the light-emitting diode 10 thus configured will be described with reference to the drawings.

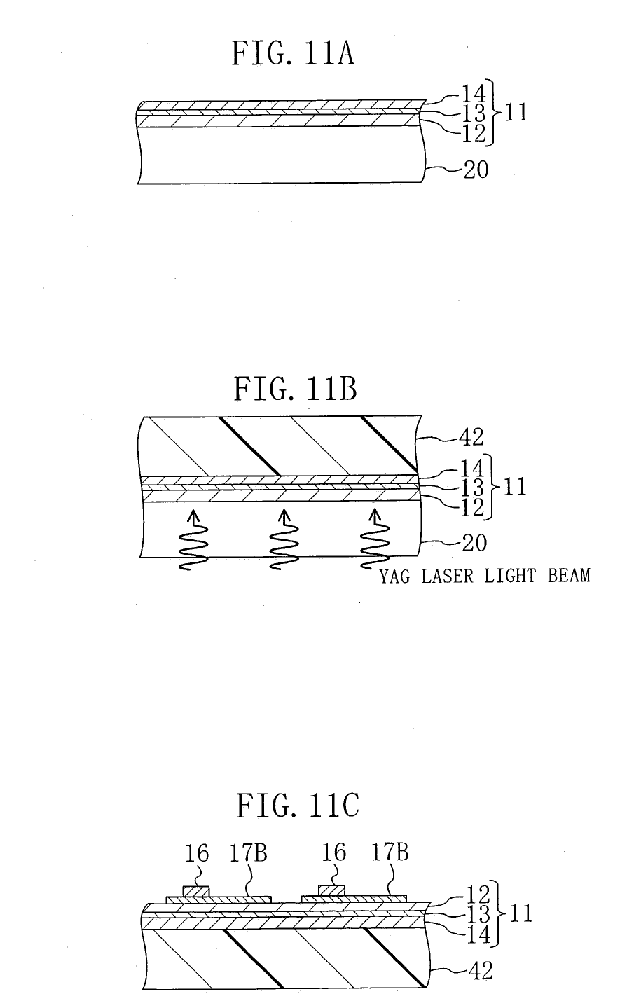

FIGS. 11A through 11C through FIGS. 13A through 13C show cross-sectional structures in respective process steps of a method for fabricating a light-emitting diode according to the third embodiment.

First, as shown in FIG. 11A, an n-type semiconductor layer 12 of n-type AlGaN, an active layer 13 of InGaN and a p-type semiconductor layer 14 of p-type AlGaN are grown in this order by, for example, an MOCVD process over the principal surface of a substrate 20 made of sapphire in wafer state, thereby forming an element structure 11 including the n-type semiconductor layer 12, active layer 13 and p-type semiconductor layer 14.

Next, as shown in FIG. 11B, a first supporting film 42 of a polymer film with a thickness of, for example, about 100 μm, is bonded onto the p-type semiconductor film 14 of the element structure 11. In this case, a polymer film of, for example, polyester having, at its supporting face, an adhesive layer which foams to lose its adhesive power when heated at about 120° C. is used as the first supporting film 42. Subsequently, the surface of the substrate 20 opposite to the element structure 11 is irradiated with a pulsing YAG laser third-harmonic light beam with a wavelength of 355 nm such that the substrate 20 is scanned. As described above, the applied laser light beam is not absorbed in the substrate 20 but is absorbed in the element structure 11, i.e., the n-type semiconductor layer 12. This light absorption causes the n-type semiconductor layer 12 to generate heat locally, so that the bonding of atoms is cut off at the interface between the n-type semiconductor layer 12 and the substrate 20, thereby forming a thermal decomposition layer (not shown) containing metal gallium between the substrate 20 and the n-type semiconductor layer 12. The light source for the laser light beam to be applied is not limited to the YAG laser third-harmonic light beam and may be a KrF excimer laser light beam with a wavelength of 248 nm. Instead of these sources for laser light beam, an emission line of a mercury lamp with a wavelength of 365 nm may be used.

Thereafter, as shown in FIG. 11C, the thermal decomposition layer is dissolved by wet etching using, for example, hydrochloric acid, thereby separating and removing the substrate 20 from the element structure 11. Then, an ITO film is deposited by, for example, an RF sputtering process over the surface of the n-type semiconductor layer 12 of the element structure 11, from which the substrate 20 has been removed, opposite to the active layer 13, and the deposited ITO film is patterned, thereby forming n-side electrodes 17B. Then, an electrode film of Au is evaporated and deposited by, for example, an electron beam evaporation process onto the n-side electrodes 17B, and the evaporated and deposited electrode film is patterned so as to cover respective parts of the n-side electrodes 17B, thereby forming bonding pads 16 out of the electrode film. In this case, the electrode film preferably has a thickness of 500 nm or more. The ITO film and the electrode film may be patterned at a time.

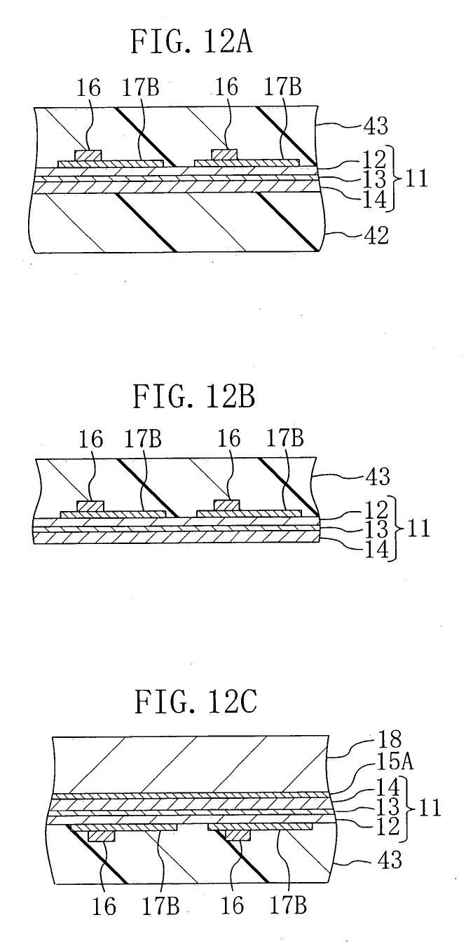

Subsequently, as shown in FIG. 12A, a second supporting film 43 of a polymer film with a thickness of, for example, about 100 μm, is bonded onto the n-type semiconductor layer 12 including the bonding pads 16 and the n-side electrodes 17B. As the second supporting film 43, a polymer film of, for example, polyester having, at its supporting face, an adhesive layer which foams to lose its adhesive power when heated at about 170° C. is used.

Then, the element structure 11 supported by the first and second supporting films 42 and 43 is heated to about 120° C. This heating at about 120° C. causes the adhesive layer provided in the first supporting film 42 to foam and to reduce its adhesive power between the element structure 11 and the p-type semiconductor layer 14, so that the first supporting film 42 is easily separated from the p-type semiconductor layer 14, as shown in FIG. 12B. At this time, there is no possibility that the adhesive of the first supporting film 42 remains on the surface of the p-type semiconductor layer 14.

Then, as shown in FIG. 12C, a p-side electrode 15A including a Pt layer with a thickness of about 50 nm and an Au layer with a thickness of about 200 nm is formed by an electron beam evaporation process on the entire surfaces of the p-type semiconductor layer 14. Subsequently, a metal film 18 is deposited by a gold plating process to a thickness of about 50 μm over the p-side electrode 15A using an Au layer of the p-side electrode 15A as an underlying layer.

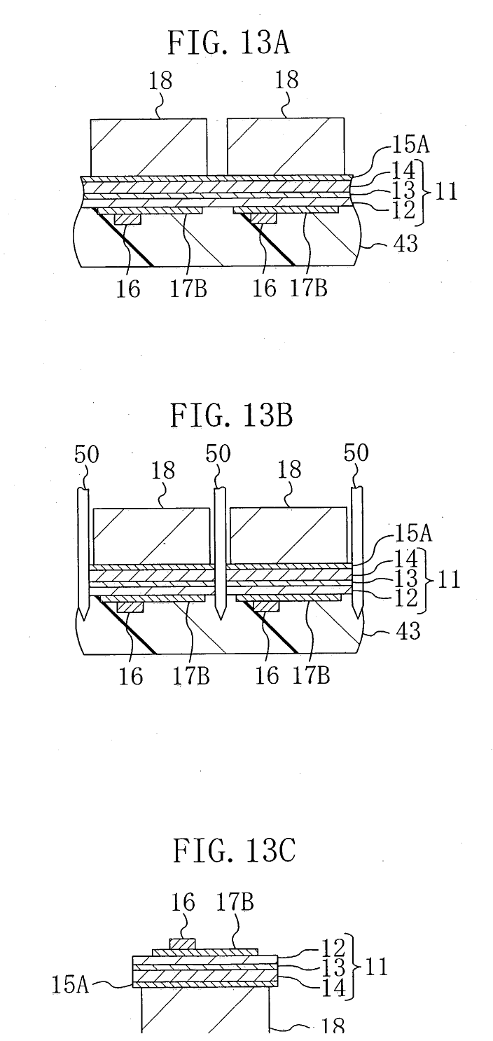

Thereafter, as shown in FIG. 13A, part of the metal film 18 associated with a chip-dividing region of the element structure 11 is selectively etched, thereby exposing a chip-dividing region of the p-side electrode 15A. In the third embodiment, the step of separating the substrate 20 and the steps of depositing respective films for the n-side electrodes 17B and the bonding pads 16 are also performed with the first supporting film 42 provided on the element structure 11, and the step of depositing respective films for the p-side electrode 15A and the metal film 18 and the step of etching the metal film 18 are also performed with the second supporting film 43 provided on the element structure 11. Accordingly, even if the element structure 11 is extremely thin, for example, as thin as about 5 μm, these steps can be performed without creating any problem.

Next, as shown in FIG. 13B, an exposed region (dicing region) of the p-side electrode 15A, which is supported by the second supporting film 43, exposed from the metal film 18 and respective portions located under the exposed region are cut off with a dicing blade 50. In this manner, a light-emitting diode chip which measures, for example, 300 μm per side in plane size is obtained. In this case, the second supporting film 43 is cut halfway.

Then, as shown in FIG. 13C, the second supporting film 43 is heated to about 170° C. so that the adhesive layer provided in the second supporting film 43 foams to reduce its adhesive power between the second supporting film 43 and the chips, thereby easily separating the respective chips from the second supporting film 43. After this removal, the chips are bonded in a subsequent step for assembly such as dice bonding.

As described above, according to the fabrication method of the third embodiment, it is possible to obtain the light-emitting diode 10 that exhibits high luminance, excellent heat radiation and high resistance to electrostatic breakdown, and has low series resistance

Embodiment 4

Hereinafter, a fourth embodiment of the present invention will be described with reference to the drawings.

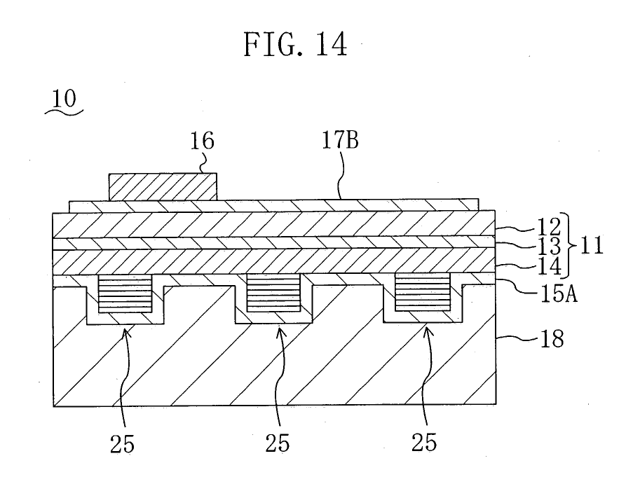

FIG. 14 shows a cross-sectional structure of a light-emitting diode which is a semiconductor light-emitting device according to the fourth embodiment and is capable of emitting short-wavelength light such as blue or green light. In FIG. 14, each member already shown in FIG. 10 is identified by the same reference numeral and the description thereof will be omitted herein.

As shown in FIG. 14, the fourth embodiment is characterized in that a plurality of mirror structures 25, each of which is made by alternately stacking first dielectric layers of, for example, silicon dioxide (SiO₂) and second dielectric layers of, for example, tantalum oxide (Ta₂O₅) having a refractive index greater than that of silicon dioxide, are formed between the p-type semiconductor layer 14 and the p-side electrode 15A of the element structure 11, being spaced from each other.

In each of the mirror structures 25, a first dielectric layer with a thickness of 80 nm and a second dielectric layer with a thickness of 53 nm constitute one set, and ten sets of such first and second dielectric layers are stacked. In this case, each of the dielectric layers is designed to have a thickness with which the maximum reflectance is λ/4 (where the wavelength of emitted light is 470 nm and the optical wavelength is ?).

The active layer 13 may have a quantum well structure, for example. Emission of blue light produced in the active layer 13 and having a wavelength of, for example, 470 nm is reflected from the p-side electrode 15A of Pt/Au and each of the mirror structures 25 and is taken out to the outside through an n-side electrode 17B of ITO.

As described above, in the fourth embodiment, the metal p-side electrode 15A, provided to have a reflectance of 90% or higher with respect to light emitted from the active layer 13, and the dielectric mirror structures 25, having a high reflectance of 90% or higher for the emitted light, are formed on the lower side of the element structure 11 constituting the light-emitting diode 10. In this manner, the light emitted from the active layer 13 is reflected from the p-side electrode 15A and the mirror structures 25 and is taken out through a transparent n-side electrode 17B provided on an n-type semiconductor layer 12, thus greatly enhancing the light extraction efficiency.

In addition, a metal film 18 is provided on the surface of the p-side electrode 15A opposite to the element structure 11 (i.e., lower surface of the p-side electrode 15A), instead of a substrate of a single crystal. Accordingly, heat generated in the active layer 13 is released to the outside via the metal film 18. By thus providing the metal film 18 replacing a single-crystal substrate to grow the element structure 11 of GaN-based semiconductors thereon, heat radiation improves significantly, thus allowing high-output operation of the light-emitting diode 10 of this embodiment. Further, since the light-emitting device 10 includes no insulating substrate such as a sapphire substrate, resistance to electrostatic breakdown is enhanced.

In the fourth embodiment, the stacked dielectric films are used for the mirror structures 25. However, the present invention is not limited to this specific embodiment. Alternatively, a multilayer film of, for example, epitaxially-grown GaN-based semiconductors may be used to create a difference in refractive index between adjacent films by making the contents of aluminum (Al) and indium (In) contained in one of the adjacent films differ from those contained in the other so that light emitted from the active layer 13 is reflected with high reflectance.

Hereinafter, a method for fabricating the light-emitting diode 10 thus configured will be described with reference to the drawings.

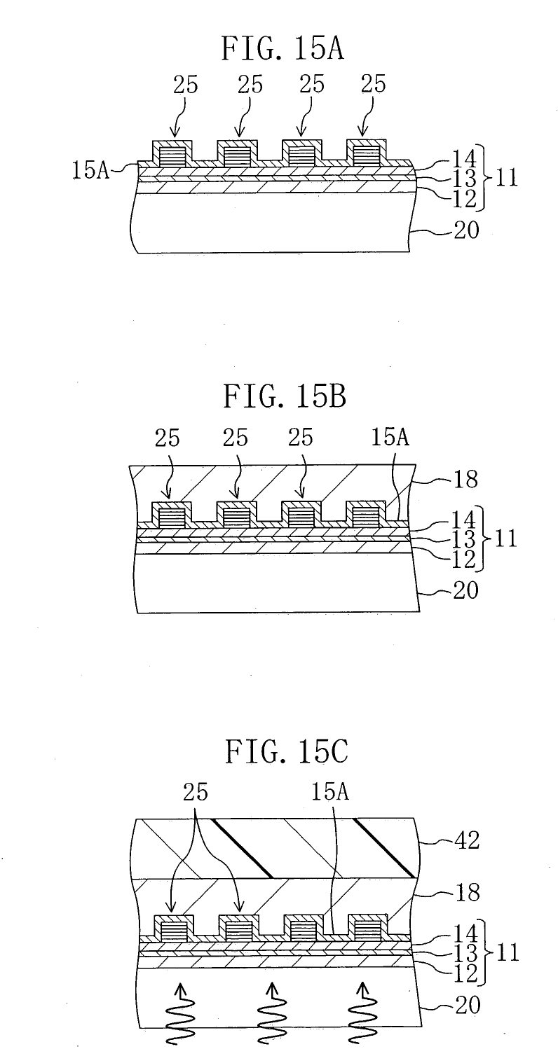

FIGS. 15A through 15C through FIGS. 17A through 17C show cross-sectional structures in respective process steps of a method for fabricating a light-emitting diode according to the fourth embodiment.

First, as shown in FIG. 15A, an n-type semiconductor layer 12 of n-type AlGaN, an active layer 13 of InGaN and a p-type semiconductor layer 14 of p-type AlGaN are grown in this order by an MOCVD process over the principal surface of a substrate 20 made of sapphire in wafer state, thereby forming an element structure 11 including the n-type semiconductor layer 12, active layer 13 and p-type semiconductor layer 14.

Subsequently, a first dielectric layer of SiO₂ with a thickness of 80 nm and a second dielectric layer of Ta₂O₅ with a thickness of 53 nm are deposited ten times (10 cycles), thereby forming a dielectric multilayer film made of ten sets of first and second dielectric layers (where one set is made up of one first dielectric layer and one second dielectric layer). Thereafter, the resultant dielectric multilayer film is wet-etched using, for example, hydrofluoric acid (HF), thereby forming a plurality of mirror structures 25 that are spaced from each other, out of the dielectric multilayer film. Subsequently, a p-side electrode 15A including a Pt layer with a thickness of about 50 nm and an Au layer with a thickness of about 200 nm is formed by an electron beam evaporation process over the entire surface of the mirror structures 25 and an exposed region of the p-type semiconductor layer 14 exposed from the mirror structures 25.

Next, as shown in FIG. 15B, a metal film 18 is deposited by a gold plating process to a thickness of about 50 μm over the p-side electrode 15A using an Au layer of the p-side electrode 15A as an underlying layer.

Then, as shown in FIG. 15C, a first supporting film 42 of a polymer film with a thickness of, for example, about 100 μm, is bonded onto the metal film 18. In this case, a polymer film of, for example, polyester having, at its supporting face, an adhesive layer which foams to lose its adhesive power when heated at about 120° C. is used as the first supporting film 42. Subsequently, the surface of the substrate 20 opposite to the element structure 11 is irradiated with a pulsing YAG laser third-harmonic light beam with a wavelength of 355 nm such that the substrate 20 is scanned. As described above, the applied laser light beam is not absorbed in the substrate 20 but is absorbed in the element structure 11, i.e., the n-type semiconductor layer 12. This light absorption causes the n-type semiconductor layer 12 to generate heat locally, so that the bonding of atoms is cut off at the interface between the n-type semiconductor layer 12 and the substrate 20, thereby forming a thermal decomposition layer (not shown) containing metal gallium between the substrate 20 and the n-type semiconductor layer 12. The light source for the laser light beam to be applied is not limited to the YAG laser third-harmonic light beam and may be a KrF excimer laser light beam with a wavelength of 248 nm. Instead of these sources for laser light beam, an emission line of a mercury lamp with a wavelength of 365 nm may be used.

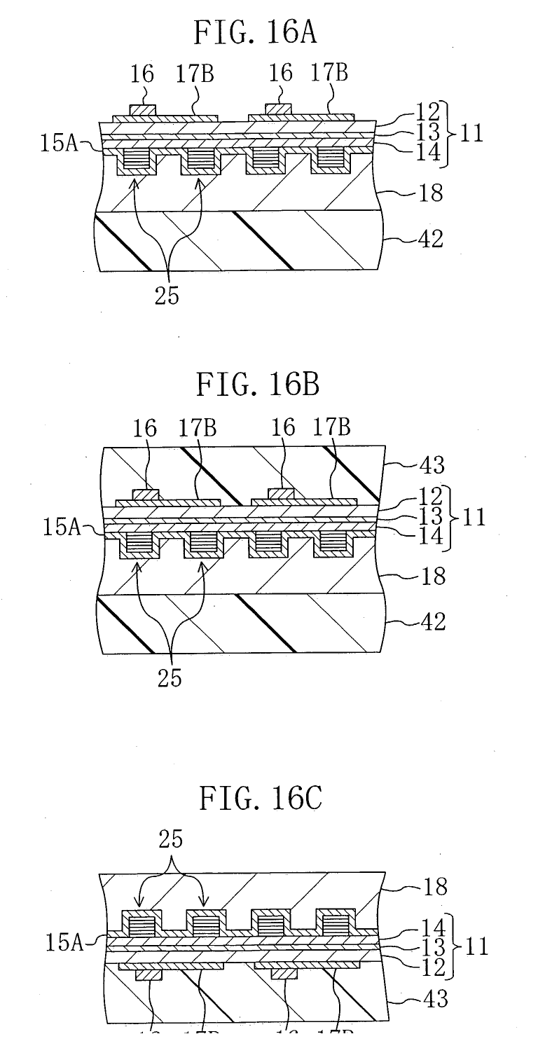

Thereafter, as shown in FIG. 16A, the thermal decomposition layer is dissolved by wet etching using, for example, hydrochloric acid, thereby separating and removing the substrate 20 from the element structure 11. Then, an ITO film is deposited by, for example, an RF sputtering process over the surface of the n-type semiconductor layer 12 of the element structure 11, from which the substrate 20 has been removed, opposite to the active layer 13, and the deposited ITO film is patterned, thereby forming n-side electrodes 17B. Then, an electrode film of Au is evaporated and deposited by, for example, an electron beam evaporation process onto the n-side electrodes 17B, and the evaporated and deposited electrode film is patterned so as to cover respective parts of the n-side electrodes 17B, thereby forming bonding pads 16 out of the electrode film. In this case, the electrode film has a thickness of 500 nm or more, e.g., about 800 nm, thus performing wire bonding on the bonding pads 16 as intended. The ITO film and the electrode film may be patterned at a time.

Subsequently, as shown in FIG. 16B, a second supporting film 43 of a polymer film with a thickness of, for example, about 100 μm, is bonded onto the n-type semiconductor layer 12 including the bonding pads 16 and the n-side electrodes 17B. As the second supporting film 43, a polymer film of, for example, polyester having, at its supporting face, an adhesive layer which foams to lose its adhesive power when heated at about 170° C. is used.

Then, the element structure 11 supported by the first and second supporting films 42 and 43 is heated to about 120° C. This heating at about 120° C. causes the adhesive layer provided in the first supporting film 42 to foam and to reduce its adhesive power to the metal film 18, so that the first supporting film 42 is easily separated from the metal film 18, as shown in FIG. 16C. At this time, there is no possibility that the adhesive of the first supporting film 42 remains on the surface of the metal film 18.

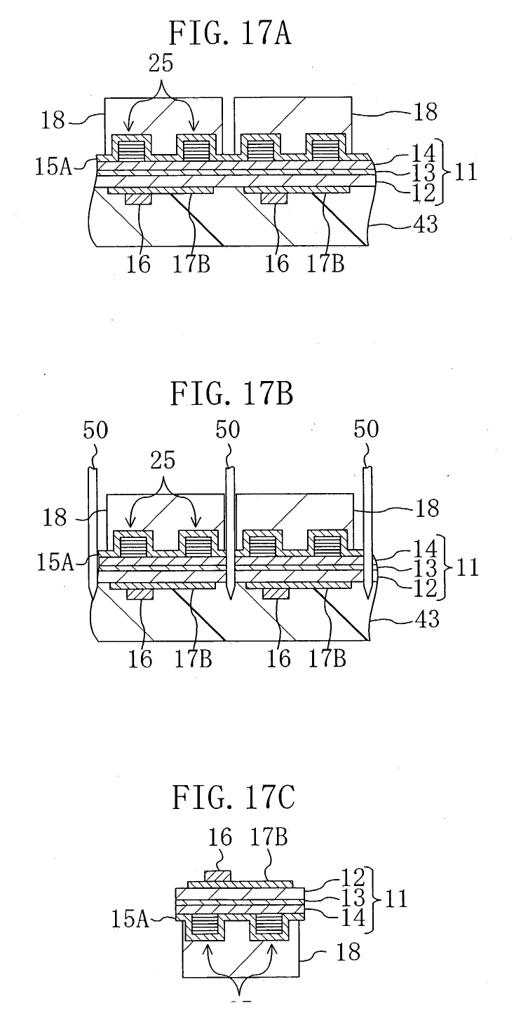

Thereafter, as shown in FIG. 17A, part of the metal film 18 associated with a chip-dividing region of the element structure 11 is selectively etched, thereby exposing a chip-dividing region of the p-side electrode 15A. In the fourth embodiment, the step of separating the substrate 20 and the steps of depositing respective films for the n-side electrodes 17B and the bonding pads 16 are also performed with the first supporting film 42 provided on the element structure 11, and the step of depositing respective films for the p-side electrode 15A and the metal film 18 and the step of etching the metal film 18 are also performed with the second supporting film 43 provided on the element structure 11. Accordingly, even if the element structure 11 is extremely thin, for example, as thin as about 5 μm, these steps can be performed without creating any problem.

Next, as shown in FIG. 17B, an exposed region (dicing region) of the p-side electrode 15A, which is supported by the second supporting film 43, exposed from the metal film 18 and respective portions located under the exposed region are cut off with a dicing blade 50. In this manner, a light-emitting diode chip which measures, for example, 300 μm per side in plane size is obtained, out of the element structure 11. In this case, the second supporting film 43 is cut halfway.

Then, as shown in FIG. 17C, the second supporting film 43 is heated to about 170° C. so that the adhesive layer provided in the second supporting film 43 foams and reduces its adhesive power between the second supporting film 43 and the chips, thereby easily separating the respective chips from the second supporting film 43. After this removal, the chips are bonded in a subsequent step for assembly such as dice bonding.

As described above, according to the fabrication method of the fourth embodiment, it is possible to obtain the light-emitting diode 10 that exhibits high luminance, excellent heat radiation and high resistance to electrostatic breakdown, and has low series resistance The mirror structures 25 are not limited to a multilayer structure of silicon dioxide (SiO₂) and tantalum oxide (Ta₂O₅). Instead of tantalum oxide that is a high-refractive-index material constituting the second dielectric layer, titanium oxide (TiO₂), niobium oxide (Nb₂O₅) or hafnium oxide (HfO₂) may be used.

In the case where the mirror structures are formed to have a high reflectance by changing the composition of aluminum gallium indium nitride (AlₓGa_{y}In_{1-x-y}N) (where 0≦x, y≦1 and 0≦x+y≦1) instead of using the multilayer film made of a dielectric, films for the element structure 11 shown in FIG. 15A are formed in the manner of successive epitaxial growths, so that no film-deposition apparatus for depositing dielectric films is needed any more. It is sufficient to perform a reactive ion etching (RIE) process using, for example, chlorine (Cl₂) gas in the patterning step for obtaining the plurality of mirror structures 25 out of the deposited semiconductor films.

In the first through fourth embodiments, the surface orientation in the principal surface of the substrate 20 is not limited. For example, in the case of sapphire, the principal surface may have a typical (0001) plane or may be in an off-orientation, which is a surface orientation slightly inclined from the general plane.

The method for crystal growth of the element structure 11 to be grown on the substrate 20 is not limited to the MOCVD process. Alternatively, the method may be a molecular beam epitaxy (MBE) process or a hydride vapor phase epitaxy (HVPE) process, or these three processes for crystal growth may be properly used in accordance with each of the semiconductor layers.

It is sufficient for the element structure 11 of GAN-based semiconductors to include a layer which absorbs irradiating light. The layer absorbing the irradiating light is not necessarily in contact with the substrate 20. The semiconductor layer absorbing the irradiating light may be made of a Group 11-V nitride semiconductor having any composition such as AlGaN or InGaN.

In addition, a light-absorbing layer having a forbidden-band width smaller than that of GaN, such as a layer of InGaN or ZnO, may be provided between the substrate 20 and the element structure 11. Then, the light-absorbing layer promotes the absorption of irradiating light, so that the light-absorbing layer is decomposed even with irradiating light with low output power.

Moreover, the laser light beam, for example, may be applied with the substrate 20 heated at such a temperature that does not cause the adhesive power of the supporting film 41, for example, to decrease. Then, a semiconductor layer of the element structure 11 can be thermally decomposed, while reducing the stress caused by the difference in thermal expansion coefficient between the substrate 20 and the element structure 11. Accordingly, it is possible to prevent a crack from occurring in the element structure 11.

Furthermore, in order to ease handling of the substrate 20 and the element structure 11, a supporting substrate of a semiconductor such as silicon (Si), gallium arsenide (GaAs), indium phosphide (InP) or gallium phosphide (GaP) or a supporting member of a metal such as copper (Cu) may be bonded onto the element structure 11 and then may be removed, before or after the step of applying light.

In the second through fourth embodiments, as in the modified example of the first embodiment, the element structure 11 may be grown again after the thermal decomposition layer has been formed between the substrate 20 and the underlying layer.

In the first, third and fourth embodiments, as in the second embodiment, a current-confinement film may be provided in the periphery of the chip.

What is claimed is:

1. A semiconductor light-emitting device comprising:
a semiconductor multilayer film including at least two semiconductor layers having mutually different conductivity types;
a first electrode formed on a surface of the semiconductor multilayer film;
a second electrode formed on the opposite surface of the semiconductor multilayer film; and
a metal film formed to be in contact with one of the first and second electrodes and having a thickness greater than or equal to that of the semiconductor multilayer film.

2. The semiconductor light-emitting device of claim 1, wherein the semiconductor multilayer film is made of a Group III-V compound semiconductor containing nitrogen as a Group V element.

3. The semiconductor light-emitting device of claim 1, wherein the metal film has a thickness of 10 μm or more.

4. The semiconductor light-emitting device of claim 1, wherein the metal film is made of gold, copper or silver.

5. The semiconductor light-emitting device of claim 1, wherein the metal film is made of plating.

6. The semiconductor light-emitting device of claim 1, wherein the metal film includes a metal layer located at the side thereof opposite to the semiconductor multilayer film and having a melting point of 300° C. or less.

7. The semiconductor light-emitting device of claim 6, wherein the metal layer contains tin.

8. The semiconductor light-emitting device of claim 1, wherein said one of the first and second electrodes that is in contact with the metal film has a reflectance of 90% or higher with respect to light emitted from the semiconductor multilayer film.

9. The semiconductor light-emitting device of claim 1, wherein said one of the first and second electrodes that is in contact with the metal film is formed out of a single layer made of at least one material selected from the group consisting of gold, platinum, copper, silver and rhodium or a multilayer film including at least two of these materials.

10. The semiconductor light-emitting device of claim 1, including a mirror structure formed between the semiconductor multilayer film and the metal film and made of a dielectric or a semiconductor, wherein
the mirror structure has a reflectance of 90% or higher with respect to light emitted from the semiconductor multilayer film.

11. The semiconductor light-emitting device of claim 10, wherein the mirror structure contains one of silicon oxide, titanium oxide, niobium oxide, tantalum oxide and hafnium oxide or aluminum gallium indium nitride (AlₓGa_{y}In_{1-x-y}N) (where 0≦x, y≦1 and 0≦x+y≦1) and is formed to have a refractive index varying cyclically with respect to the wavelength of the light emitted from the semiconductor multilayer film.

12. The semiconductor light-emitting device of claim 1, wherein one of the first and second electrodes provided on the surface of the semiconductor multilayer film opposite to the metal film is transparent.

13. The semiconductor light-emitting device of claim 1, wherein one of the first and second electrodes provided on the surface of the semiconductor multilayer film opposite to the metal film is made of indium tin oxide or a metal containing nickel and having a thickness of 20 nm or less.

14. The semiconductor light-emitting device of claim 1, including a current-confinement film which is made of a dielectric and is formed between the semiconductor multilayer film and the metal film at the peripheries of the semiconductor multilayer film and the metal film.

15. A method for fabricating a semiconductor light-emitting device, comprising the steps of:
a) forming, on a substrate of a single crystal, a semiconductor multilayer film including at least two semiconductor layers having mutually different conductivity types;
b) separating the substrate from the semiconductor multilayer film;
c) forming a first electrode on a surface of the semiconductor multilayer film and forming a second electrode on the opposite surface of the semiconductor multilayer film, and
d) forming a metal film over one of the first and second electrodes.

16. The method of claim 15, wherein the semiconductor multilayer film is made of a Group III-V compound semiconductor containing nitrogen as a Group V element.

17. The method of claim 15, wherein in the step b), irradiating light having a wavelength at which the light passes through the substrate and is absorbed in part of the semiconductor multilayer film is applied onto the surface of the substrate opposite to the semiconductor multilayer film, so that a decomposition layer is formed inside the semiconductor multilayer film by decomposition of part of the semiconductor multilayer film, thereby separating the substrate from the semiconductor multilayer film.

18. The method of claim 17, wherein the irradiating light is pulsing laser light beam.

19. The method of claim 17, wherein the irradiating light is an emission line of a mercury lamp.

20. The method of claim 17, wherein the irradiating light is applied such that the substrate is scanned within the surface thereof.

21. The method of claim 17, wherein the irradiating light is applied, while heating the substrate.

22. The method of claim 15, wherein in the step b), the substrate is removed by polishing, thereby separating the substrate from the semiconductor multilayer film.

23. The method of claim 15, wherein the step a) includes the steps of:
partially forming the semiconductor multilayer film, and then applying irradiating light, having a wavelength at which the light passes through the substrate and is absorbed in the semiconductor multilayer film, onto the surface of the substrate opposite to the semiconductor multilayer film, thereby decomposing part of the semiconductor multilayer film to form a decomposition layer inside the partially formed semiconductor multilayer film; and
forming the rest of the semiconductor multilayer film on the partially formed semiconductor multilayer film, after the decomposition layer has been formed.

24. The method of claim 15, including the step e) of forming another multilayer film made of a dielectric or a semiconductor on the semiconductor multilayer film, and then patterning said another multilayer film, between the steps a) and b),
wherein in the step c), one of the first and second electrodes is formed on the patterned multilayer film, and
in the step d), the metal film is formed on the electrode formed on the patterned multilayer film.

25. The method of claim 24, wherein in the step c), the other one of the first and second electrodes is formed on the surface of the semiconductor multilayer film opposite to the multilayer film after the substrate has been separated from the semiconductor multilayer film.

26. The method of claim 15, including the steps of:
f) bonding a first supporting member in film form for supporting the semiconductor multilayer film onto the semiconductor multilayer film, the first supporting member being made of a material different from a material constituting the semiconductor multilayer film, between the steps of a) and b); and
g) peeling off the first supporting member from the semiconductor multilayer film, after the step b) has been performed.

27. The method of claim 26, including the steps of
h) bonding a second supporting member in film form having different properties from those of the first supporting member onto the surface of the semiconductor multilayer film opposite to the first supporting member, before the step g) is performed; and
i) peeling off the second supporting member from the semiconductor multilayer film, after the step g) has been performed.

28. The method of claim 26, wherein the first or second supporting member is a polymer film, a single-crystal substrate made of a semiconductor, or a metal plate.

29. The method of claim 28, wherein the polymer film is provided, at a bonding surface thereof, with an adhesive layer that can be peeled off when heated.

30. The method of claim 15, including the step i) of selectively forming a current-confinement film of a dielectric on the semiconductor multilayer film, before the step c) is performed.

31. A method for bonding a semiconductor light-emitting device, comprising the steps of:
a) forming, on a substrate of a single crystal, a semiconductor multilayer film including at least two semiconductor layers having mutually different conductivity types;
b) bonding a supporting member in film form for supporting the semiconductor multilayer film onto the semiconductor multilayer film, the supporting member being made of a material different from a material constituting the semiconductor multilayer film; and
c) dicing the semiconductor multilayer film and the supporting member together, thereby forming a plurality of chips which are supported by the supporting member having been divided into respective pieces; and
d) performing dice bonding on the chips supported by the supporting member, and then peeling off the supporting member from the chips.

32. The method of claim 31, wherein the supporting member is a polymer film.

33. The method of claim 31, wherein the polymer film is provided with, at a bonding surface thereof, an adhesive layer which can be peeled off when heated.
